(19) United States
(12) Patent Application Publication
(10) Pub. No.: US 2006/0104032 A1
(43) Pub. Date: May 18, 2006

(54) Heat dissipation device

(75) Inventors: Hsieh-Kun Lee, Tu-Cheng (TW); Cheng-Tien Lai, Tu-Cheng (TW); Zhi-Yong Zhou, Shenzhen (CN); Jiang-jian Wen, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: Hon Hai Precision Industry Co., LTD

(21) Appl. No.: 10/989,761

(22) Filed: Nov. 16, 2004

(51) Int. Cl. H05K 7/20

(52) U.S. Cl. 361/700

(57) ABSTRACT

A heat dissipation device for an electronic unit includes a heat sink and at least a heat pipe. The heat sink includes a base for contacting with the electronic unit and a plurality of fins arranged on the base to create a first heat transfer path for the electronic unit. The heat pipe is attached to the heat sink and includes an evaporating portion for contacting with the electronic unit, and a condensing portion thermally contacting with the fins to create a second heat transfer path for the electronic unit.

### TECHNICAL FIELD

The present invention relates to a heat dissipation device, and particularly to a heat dissipation device including a heat sink and heat pipes for achieving great heat dissipation efficiency.

### BACKGROUND

As computer technology continues to advance, electronic components such as central processing units (CPUs) of computers are made to provide faster operational speeds and greater functional capabilities. When a CPU operates at a high speed in a computer enclosure, its temperature usually increases greatly. It is desirable to dissipate the generated heat of the CPU quickly.

Conventionally, a heat dissipation device is used to dissipate heat generated by a CPU. Referring to FIG. 4 and FIG. 5, a conventional heat dissipation device comprises a heat sink 100 and a pair of heat pipes 200 thermally contacting with the heat sink 100. The heat sink 100 is made of metal material with good heat conductivity and comprises two spaced flat bases 102 each defining two holes therein, and a plurality of parallel fins 104 extending from one base 102 to the other base 102. One base 102 is for contacting with a CPU 300. The heat pipe 200 is U-shaped. Two ends of each heat pipe 200 respectively extend into the corresponding holes of the two bases 102. When the heat dissipation device is used, the base 102 contacting with the CPU 300 absorbs heat from the CPU 300. Some of the heat accumulated at the base 102 is transferred to the bottom portion of the fins 104 to create a first heat transfer path, while the other of the heat is transferred to the other base 102 through the heat pipes 200, and then is transferred to the upper portion of fins 104 to create a second heat transfer path. However, in the second heat transfer path, the heat generated by the CPU 300 is transferred to the heat pipes 200 through the metal base 102, and solid metal material is known to have higher heat resistance. Therefore, the heat generated by the CPU 300 can not be transmitted to the fins 104 effectively.

An improved heat dissipation device is desired to overcome the above-described disadvantage of the prior art.

### SUMMARY OF THE INVENTION

Accordingly, an object of the present invention is to provide a heat dissipation device which can quickly and efficiently transfer heat away from an electronic unit.

To achieve the above-mentioned object, a heat dissipation device for an electronic unit comprises a heat sink and at least a heat pipe. The heat sink comprises a base for contacting with the electronic unit and a plurality of fins arranged on the base to create a first heat transfer path for the electronic unit. The heat pipe is attached to the heat sink and comprises an evaporating portion for contacting with the electronic unit, and a condensing portion thermally contacting with the fins to create a second heat transfer path for the electronic unit.

Other objects, advantages and novel features of the present invention will be drawn from the following detailed description of a preferred embodiment of the present invention together with the attached drawings, in which:

### BRIEF DESCRIPTION OF THE DRAWINGS

FIG. 1 is an isometric view of a heat dissipation device in according with the preferred embodiment of the present invention;

FIG. 2 is an exploded isometric view of the heat dissipation device in FIG. 1;

FIG. 3 is a cross-sectional view taken along the line III-III of FIG. 1;

FIG. 4 is an isometric view of a conventional heat dissipation device; and

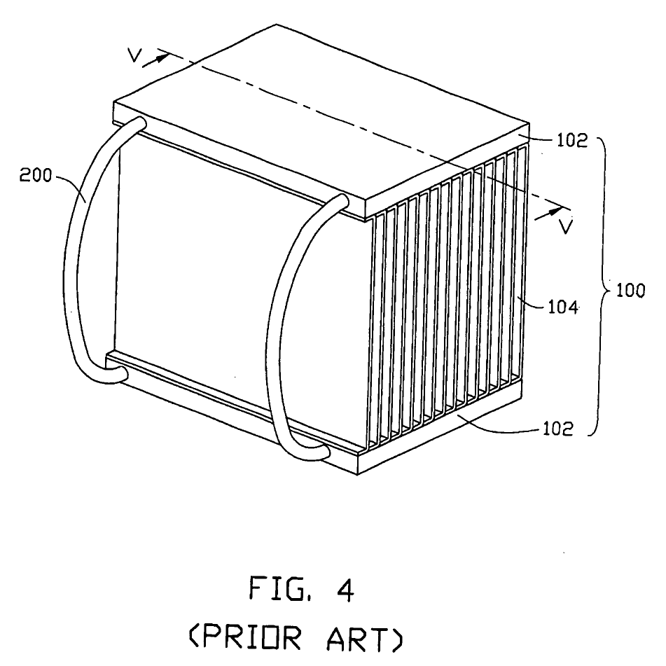

FIG. 5 is a cross-sectional view taken along the line V-V of FIG. 4.

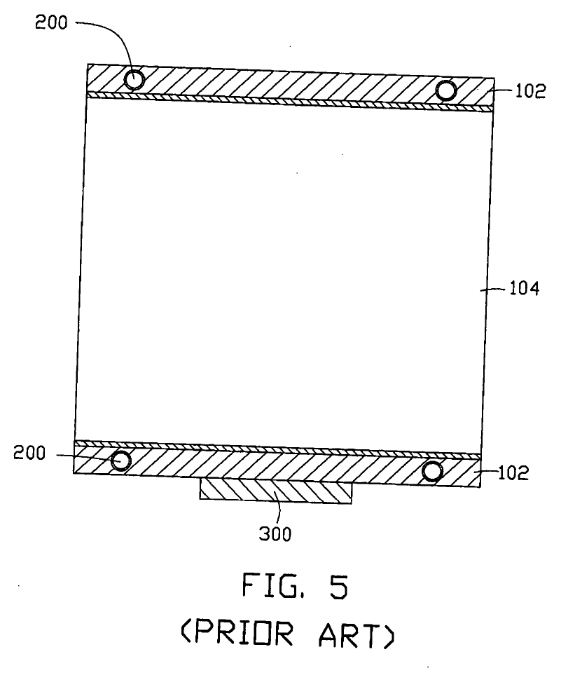

### DETAILED DESCRIPTION OF A PREFERED EMBODIMENT

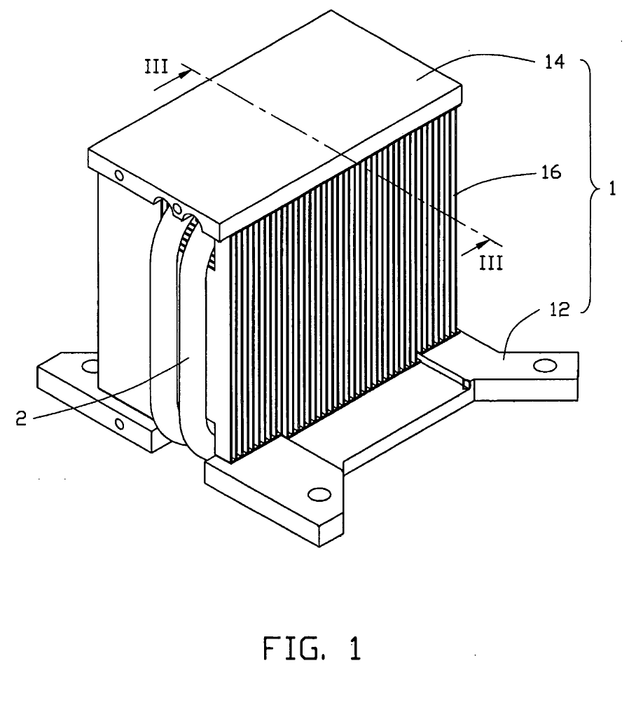

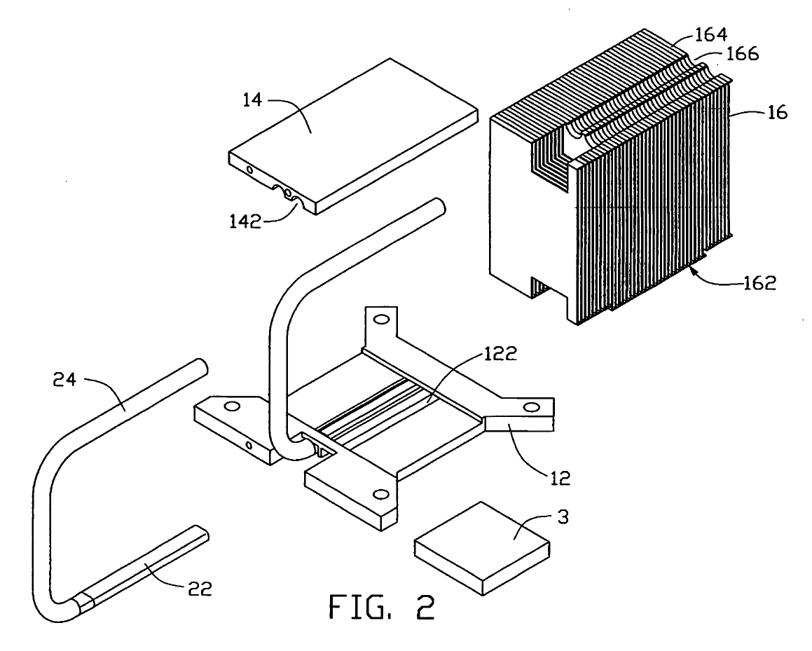

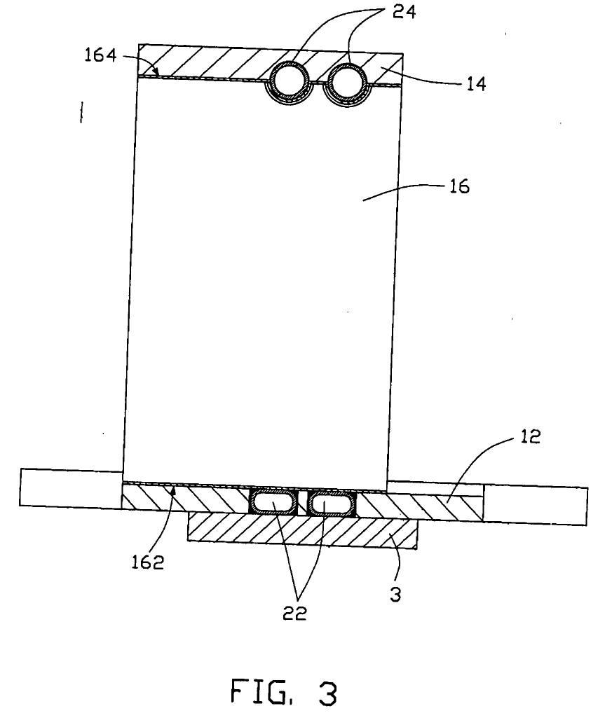

Referring to FIG. 1 to FIG. 3, a heat dissipation device in accordance with the preferred embodiment of the present invention comprises a heat sink 1 and a pair of heat pipes 2 thermally connecting with the heat sink 1.

The heat sink 1 comprises a base 12 adapted to be attached on an electronic unit 3, a plate 14 as an auxiliary member spaced from and parallel to the base 12, and a plurality of parallel fins 16 extending between the base 12 and the plate 14.

The base 12 defines a pair of slots 122. The plate 14 defines a pair of grooves 142. Opposite top and bottom edges of the fins 16 are bent to form a plurality of heat conducting flanges. The heat conducting flanges cooperatively form top and bottom surfaces 164, 162 of the fins 16. The top surface 164 of the fins 16 defines a pair of grooves 166 therein corresponding with the grooves 142 of the plate 14.

Each heat pipe 2 is U-shaped, and forms a capillary structure therein. Working medium is contained in the heat pipe 2. Opposite ends of each heat pipe 2 respectively form an evaporating portion 22 and a condensing portion 24. The evaporating portion 22 is engaged in the slot 122 of the base 12 and the condensing portion 24 is engaged in passages cooperatively formed by the groove 142 of the plate 14 and the groove 166 of the fins 16. The evaporating portion 22 of each heat pipe 2 is flat, and the bottom surface of the evaporating portion 22 is coplanar with the bottom surface of the base 12. The evaporating portion 22 of the heat pipe 2 is exposed along the top and bottom surfaces of the base 12.

The fins 16 are attached on the base 12. The bottom surface 162 of the fins 16 contacts with the top surface of the base 12, and some portions of each of the fins 16 located over the slots 122 contact with the top surfaces of the evaporating portions 22 of the heat pipes 2. The top surface 164 of the fins 16 contacts with the plate 14, and the condensing portions 24 of the heat pipes 2 contact with the fins 16 at the grooves 166.

In the present invention as illustrated by the above preferred embodiment, the connecting between the heat pipes 2 and the base 12, the heat pipes 2 and the plate 14, the heat pipes 2 and the fins 16 is by any joint way such as soldering. Some of heat generated by the electronic unit 3 is directly transferred to the base 12 and then to the fins 16 to create a first heat transfer path. The other of heat generated by the electronic unit 3 is directly transferred to the heat pipes 2 since the evaporating portions 22 of the heat pipes 2 directly contact with the electronic unit 3, and the heat pipes 2 directly transfer the heat to the fins 16 without transmitting the base 12. Therefore, a second heat transfer path is formed by the heat pipes 2 and the fins 16. In the second heat transfer path, the heat resistance is greatly reduced in comparison with the prior art.

Alternatively, the condensing portions 24 of the heat pipes 2 can extend through and connect with the fins 16 without use of the plate 14. In addition, one heat pipe 2 or more heat pipes 2 can be used, which bases on the quantity of heat generated by the electronic unit 3.

It is understood that the heat pipe 2 can be other alternative structures, such as S-shaped heat pipe having an evaporating portion and two parallel condensing portions, so far as the evaporating portion can contacts with the electronic unit 3, and the condensing portion can contacts with the portions of the fins located away from the electronic unit 3.

It is understood that the invention may be embodied in other forms without departing from the spirit thereof. Thus, the present examples and embodiments are to be considered in all respects as illustrative and not restrictive, and the invention is not to be limited to the details given therein.

What is claimed is:

1. A heat dissipation device for an electronic unit, comprising:
a heat sink comprising a base for contacting with the electronic unit and a plurality of fins arranged on the base to create a first heat transfer path for the electronic unit; and
at least a heat pipe attached to the heat sink and comprising an evaporating portion for contacting with the electronic unit, and a condensing portion thermally contacting with the fins to create a second heat transfer path for the electronic unit.

2. The heat dissipation device as described in claim 1, wherein the evaporating portion of the heat pipe is flat.

3. The heat dissipation device as described in claim 2, wherein the base of the heat sink defines at least a slot receiving the evaporating portion of said heat pipe, and the bottom surface of the evaporating portion of said heat pipe is coplanar with the bottom surface of the base.

4. The heat dissipation device as described in claim 3, wherein the fins are arranged on the top surface of the base, and some of the fins located over the slot contact with the top surface of the evaporating portion of said heat pipe.

5. The heat dissipation device as described in claim 4, wherein the heat sink further comprises a plate parallel to the base, and the fins extends between the base and the plate.

6. The heat dissipation device as described in claim 5, wherein the plate and the fins cooperatively define at least a passage for containing the condensing portion of the heat pipe.

7. The heat dissipation device as described in claim 6, wherein the heat pipe is U-shaped, and two ends of the heat pipe respectively form the evaporating portion and the condensing portion.

8. The heat dissipation device as described in claim 5, wherein opposite top and bottom edges of each fin are bent to form two flanges to contact with the base and the plate respectively.

9. A heat dissipation device for an electronic unit, comprising:
at least a heat pipe comprising an evaporating portion having a plane for contacting with the electronic unit, and at least a condensing portion; and
a heat sink comprising a plurality of fins each contacting with the evaporating portion of the heat pipe and the condensing portion of the heat pipe.

10. The heat dissipation device as described in claim 9, wherein the evaporating portion of the heat pipe is flat.

11. The heat dissipation device as described in claim 10, wherein the heat sink further comprises a base defining at least a slot for containing the evaporating portion of the heat pipe, and the evaporating portion of the heat pipe is exposed along the top and bottom surfaces of the base.

12. The heat dissipation device as described in claim 11, wherein the fins contact with the base, and the portion of the fins corresponding with the aperture contact with the evaporating portion of the heat pipe.

13. An electronic assembly comprising:
an electronic unit;
a plurality of parallel fins for dissipating heat generated by the electronic unit; and
at least a heat pipe one end thereof being sandwiched between and contacting with the electronic unit and the fins, and the other end of said heat pipe crossing through the fins away from the electronic unit.

14. The electronic assembly as described in claim 13, wherein the one end of said heat pipe sandwiched between the electronic unit and fins is flat.

15. The electronic assembly as described in claim 13, further comprising a base defining at least a slot for containing the one end of said heat pipe, the one end of the heat pipe being exposed along the top and bottom surfaces of the base, and the fins contacting with the base and the one end of said heat pipe.

16. A heat dissipation device for a heat generating unit, comprising:
a base for heat-interchange with said heat generating unit;
an auxiliary member spaced from said base;
a plurality of fins disposed between said base and said auxiliary member, each of said plurality of fins having heat-interchange with said base and said auxiliary member respectively; and
at least one heat pipe having portions embedded partially in said base and said auxiliary member respectively for heat-interchange, each of said portions having heat-interchangable contact with at least one of said plurality of fins.

17. The heat dissipation device as described in claim 16, wherein one of said portions is an evaporating portion for a working medium contained in said at least one heat pipe, and the other of said portions is a condensing portion for said working medium.

18. The heat dissipation device as described in claim 16, wherein each of said plurality of fins has a bent heat-interchange flange at edges thereof to intimately contact with said portions of said at least one heat pipe respectively.
